(19) United States
(12) Patent Application Publication
(10) Pub. No.: US 2024/0035160 A1
(43) Pub. Date: Feb. 1, 2024

(54) SUSCEPTOR SUPPORT ASSEMBLY FOR CHEMICAL VAPOR DEPOSITION CHAMBERS

(71) Applicant: Applied Materials, Inc., Santa Clara, CA (US)

(72) Inventors: Tetsuya ISHIKAWA, San Jose, CA (US); Ala MORADIAN, Sunnyvale, CA (US); Karthikeyan BALARAMAN, Bangalore (IN); Shashikanth CHENNAKESHAVA, Chikmagalur (IN)

(21) Appl. No.: 17/874,873

(22) Filed: Jul. 27, 2022

(51) Int. Cl. C23C 16/458

(52) U.S. Cl. CPC C23C 16/4584; C23C 16/4581

(57) ABSTRACT

An apparatus for rotating a substrate within a deposition chamber is described. The substrate is rotated using a substrate support assembly with a shaft and a susceptor coupled to a top of the shaft. The susceptor and the shaft are coupled together using a cogged feature. The cogged feature includes a plurality of teeth or projections on a coupling portion of the shaft which interlock with an indent disposed on the bottom of the susceptor. A lift pin assembly is further coupled to the shaft and configured to raise and lower a substrate from the susceptor.

### BACKGROUND

### Field

Embodiments of the present disclosure generally relate to a substrate support apparatus for use within a processing chamber. More specifically, the embodiments of the present disclosure are directed towards a substrate support shaft and corresponding susceptor for use within a deposition chamber for semiconductor processing.

### Description of the Related Art

Semiconductor substrates are processed for a wide variety of applications, including the fabrication of integrated devices and microdevices. One method of processing a substrate includes depositing a material, such as a semiconductor material or a conductive material, on an upper surface of the substrate. For example, epitaxial deposition is one deposition process that deposits films of various materials on a surface of a substrate in a processing chamber. Epitaxial deposition processes are able to produce high-quality films on substrates which have a crystalline structure. The epitaxial deposition processes are performed under various process conditions, such as temperature, pressures, and precursor flow rates, within the processing chambers. Quality and consistency of an epitaxial layer depends on precise temperature and flow control inside the chamber.

During deposition of a film on the substrate, the substrate is generally rotated about an axis of symmetry of the substrate. The speed and uniformity of rotation further impact the deposition of the film on the substrate surface. Tilt and wobble which are introduced into the motion of the susceptor by a variety of components within a substrate support assembly. Wobble and tilt of the susceptor reduces deposition uniformity on the substrate and increases difficulty of performing the processes and maintenance on the susceptor.

Therefore, what is needed are improved apparatus which reduce wobble and tilt of a susceptor during substrate processing.

### SUMMARY

The present disclosure generally relates to a substrate support assembly, configured for use in semiconductor processing. In one embodiment, the substrate support assembly includes a susceptor, a shaft, and a shaft coupling portion. The susceptor includes a substrate support surface, a coupling surface, and a cogged indent within the coupling surface. The shaft includes a first distal end and a second distal end opposite the first distal end. The shaft coupling portion is coupled to the first distal end of the shaft and disposed within the cogged indent.

In another embodiment, a susceptor is described. The susceptor is configured for use in semiconductor processing. The susceptor includes a substrate support surface, a coupling surface opposite the substrate support surface, and a cogged indent disposed within the coupling surface. The cogged indent further includes a central opening and a plurality of wings extending from the central opening outward across the coupling surface.

In another embodiment, a shaft is described. The shaft is configured for use in semiconductor processing. The shaft includes a first distal end, a second distal end opposite the first distal end, and a shaft coupling portion coupled to the first distal end of the shaft. The shaft coupling portion includes a coupling contact surface and a plurality of projections extending outward from a central portion of the coupling contact surface, such that the coupling contact surface is cogged.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a schematic cross-sectional view of a deposition chamber, according to one embodiment of the disclosure.

FIG. 2 is a schematic isometric view of a substrate support assembly, according to one embodiment of the disclosure.

FIG. 3A is a cross-sectional schematic view of a shaft, according to one embodiment of the disclosure.

FIG. 3B is a schematic plan view of a shaft coupling portion, according to one embodiment of the disclosure.

FIG. 4 is a schematic bottom view of a susceptor, according to one embodiment of the disclosure.

FIGS. 5A-5D are schematic views of portions of a shaft motion coupling, according to embodiments of the disclosure.

FIGS. 6A and 6B are schematic isometric views of substrate support assemblies, according to embodiments of the disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure is directed towards a substrate support assembly which includes a susceptor and a shaft. The susceptor and the shaft are coupled together using a cogged configuration. The use of the cogged configuration within the susceptor and the shaft configuration described reduces wobbling of the susceptor during substrate processing, such as during epitaxial deposition processing, and rotation of the substrate support assembly. Wobbling of the susceptor and the substrate disposed on the susceptor during processing can result in asymmetric and/or non-uniform film thickness growth.

The cogged configuration described herein reduces wobbling by providing a simple and secure coupling of the rotating shaft and the susceptor/susceptor support mechanism. Each of the susceptor, the shaft, and the lift pins which will be disposed through the shaft are one or a combination of graphite, quartz, a thermoplastic, or metal. The susceptor is a material formed of a high thermal conductivity, such as graphite. The shaft is formed of an optically transparent material to enable uniform heating of the substrate. The use of a single shaft as well as optical transparency of components of the substrate support assembly further reduce shadowing caused by the shaft and/or the lift pins. The cogged interface between the shaft and the susceptor may further be described as a spline interface or a gear interface. The use of the cogged interface further enables the distribution of stress along multiple surfaces within the interface between the shaft and the susceptor. Reduced stress reduces the deformation and probability of chipping or flaking at the interface. The shape of the cogged interface reduces stress at a single point. For example, the use of a curved contact surface on each extension/protrusion of the cogged interface assists in distributing the load along the curved surface instead of a single point or a group of points.

An interface at the bottom of the shaft to the rotation assembly further enables reduced warping and damage to the shaft by using a plurality of pins disposed between the shaft and the rotation assembly. The plurality of pins are disposed within grooves of the shaft and are held in place between the shaft and the rotation assembly coupling. The shape, configuration, and material of the pins further reduces stress on the shaft and enables rotation of the shaft and subsequently the susceptor.

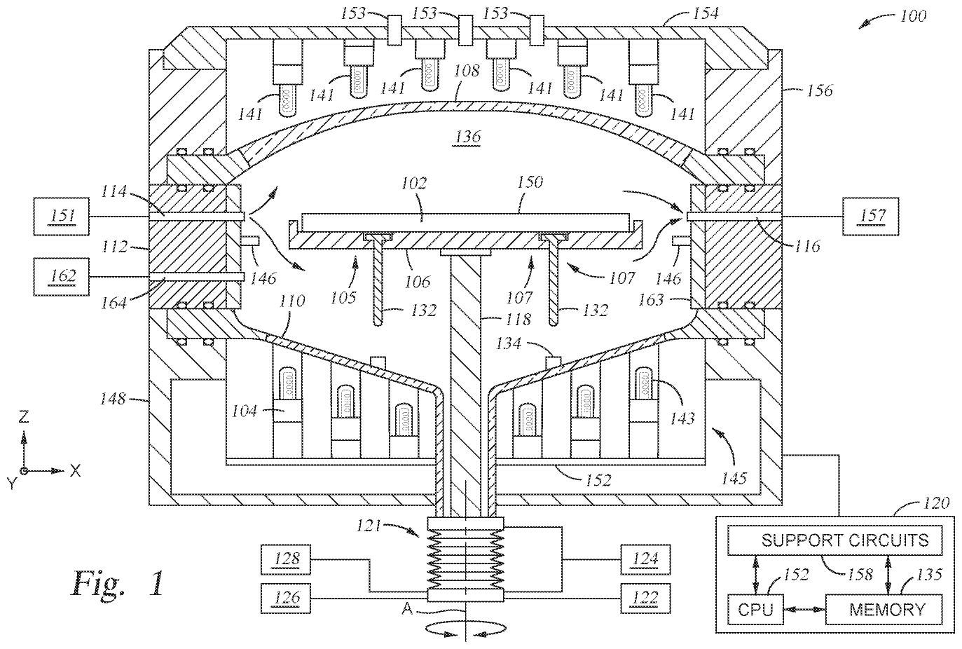

FIG. 1 is a schematic illustration of a type of deposition chamber 100. The deposition chamber 100 is utilized to grow an epitaxial film on a substrate, such as the substrate 102. The deposition chamber 100 creates a cross-flow of precursors across the top surface 150 of the substrate 102.

The deposition chamber 100 includes an upper body 156, a lower body 148 disposed below the upper body 156, a flow module 112 disposed between the upper body 156 and the lower body 148. The upper body 156, the flow module 112, and the lower body 148 form a chamber body. Disposed within the chamber body is a substrate support assembly 105, an upper dome 108, a lower dome 110, a plurality of upper lamps 141, and a plurality of lower lamps 143. As shown, the controller 120 is in communication with the deposition chamber 100 and is used to control processes, such as those described herein. The substrate support assembly 105 includes a susceptor 106 and a shaft 118 coupled to the substrate support 106. The susceptor 106 is disposed between the upper dome 108 and the lower dome 110. The plurality of upper lamps 141 are disposed between the upper dome 108 and a lid 154. The lid 154 includes a plurality of sensors 153 disposed therein for measuring the temperature within the deposition chamber 100. The plurality of lower lamps 143 are disposed between the lower dome 110 and a floor 152. The plurality of lower lamps 143 form a lower lamp assembly 145.

A processing volume 136 is formed between the upper dome 108 and the lower dome 110. The processing volume 136 has the susceptor 106 disposed therein. The susceptor 106 includes a top surface on which the substrate 102 is disposed. The shaft is connected to a motion assembly 121. The motion assembly 121 includes one or more actuators and/or adjustment devices that provide movement and/or adjustment of the substrate support assembly 105. Motion is first imparted on the shaft 118 and the shaft 118 transfers the movement to the susceptor 106 within the processing volume 136. The motion assembly 121 includes a rotary actuator 122 that rotates the shaft 118 and the susceptor 106 about a longitudinal axis A of the deposition chamber 100. The motion assembly 121 further includes a vertical actuator 124 to lift and lower the substrate support assembly 105 in the z-direction. The motion assembly 121 includes a tilt adjustment device 126 that is used to adjust the planar orientation of the susceptor 106 and a lateral adjustment device 128 that is used to adjust the position of the shaft 118 and the susceptor 106 side to side within the processing volume 136.

The susceptor 106 may include lift pin holes 107 disposed therein. The lift pin holes 107 are sized to accommodate a lift pin 132 for lifting of the substrate 102 from the susceptor 106 either before or after a deposition process is performed. The lift pins 132 may rest on lift pin stops 134 when the susceptor 106 is lowered from a processing position to a transfer position.

The flow module 112 includes a plurality of process gas inlets 114, a plurality of purge gas inlets 164, and one or more exhaust gas outlets 116. The plurality of process gas inlets 114 and the plurality of purge gas inlets 164 are disposed on the opposite side of the flow module 112 from the one or more exhaust gas outlets 116. One or more flow guides 146 are disposed below the plurality of process gas inlets 114 and the one or more exhaust gas outlets 116. The flow guide 146 is disposed above the purge gas inlets 164. A liner 163 is disposed on the inner surface of the flow module 112 and protects the flow module 112 from reactive gases used during deposition processes. The process gas inlets 114 and the purge gas inlets 164 are positioned to flow a gas parallel to the top surface 150 of a substrate 102 disposed within the processing volume 136. The process gas inlets 114 are fluidly connected to a process gas source 151. The purge gas inlets 164 are fluidly connected to a purge gas source 162. The one or more exhaust gas outlets 116 are fluidly connected to an exhaust pump 157. Each of the process gas source 151 and the purge gas source 162 may be configured to supply one or more precursors or process gases into the processing volume 136.

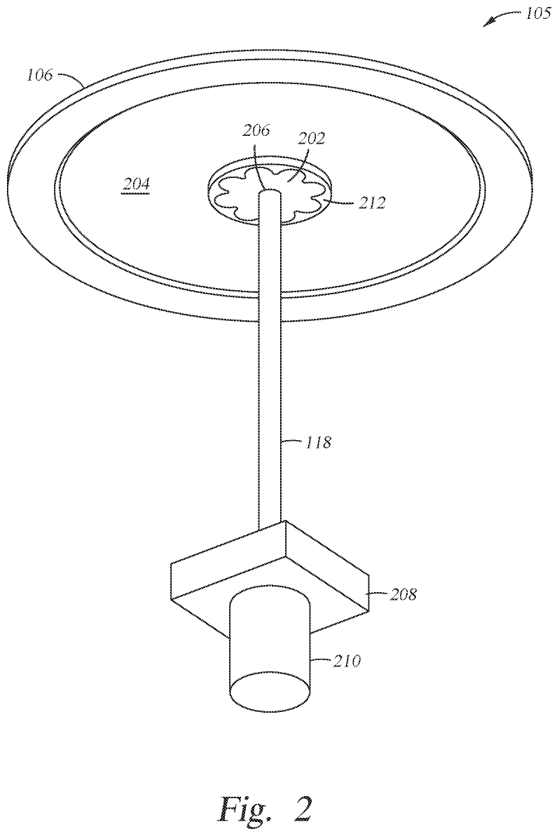

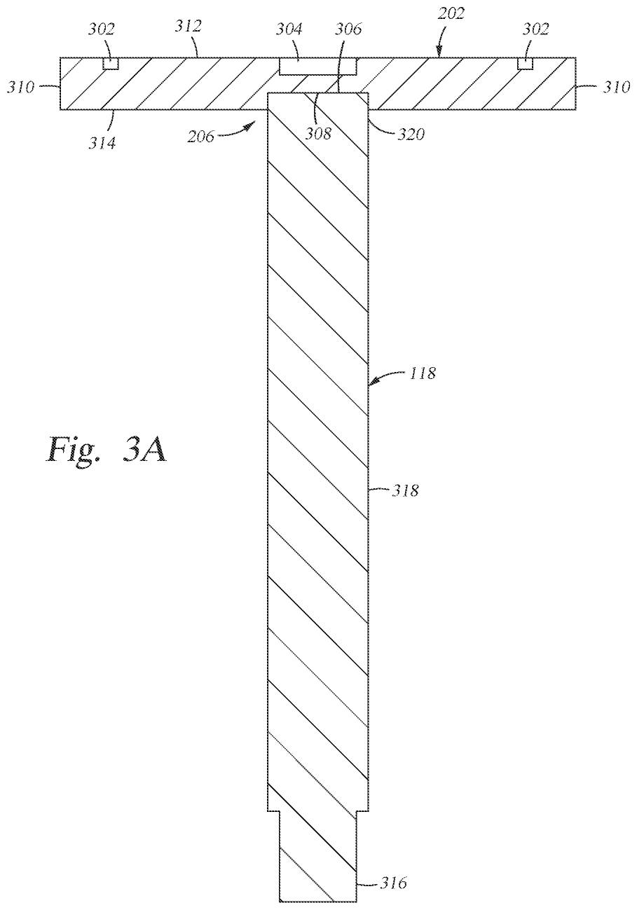

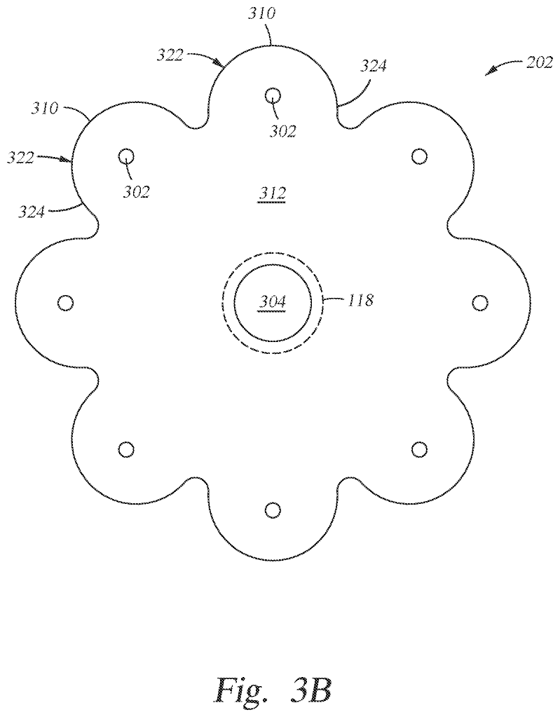

Each of FIG. 2, FIGS. 3A and 3B, FIG. 4, FIGS. 5A-5D, and FIGS. 6A and 6B illustrate either a full or a partial view of a substrate support assembly 105. The substrate support assembly 105 includes the susceptor 106 coupled at a top distal end of the shaft 118. The coupling of the susceptor 106 and the shaft 118 is performed at a shaft coupling. The shaft coupling is a cogged feature and extends into a corresponding cogged indent within the susceptor 106. The cogged feature includes multiple engagement portions extending form a central member, and is configured to distribute the load of torque imparted on the shaft and the susceptor by rotation of the susceptor and a substrate disposed on top of the susceptor. The cogged feature includes a plurality of teeth or protrusions which are meant to interlock with gaps, wings, or openings within the cogged indent. The use of a single shaft and the cogged feature to couple the susceptor 106 and the shaft 118 enables a reduction in the amount of wobble of the susceptor 106 during rotation. The cogged feature reduces or eliminates the use of multiple arms and corresponding fingers to hold the susceptor 106. The cogged feature and the shaft may further be formed of a quartz material to reduce shadowing.

FIG. 2 is a schematic isometric view of a substrate support assembly 105. The substrate support assembly includes the susceptor 106 and the shaft 118. The susceptor 106 and the shaft 118 are coupled together at a cogged interface. The cogged interface includes a susceptor coupling portion 212 within a coupling surface 204 of the susceptor 106 and a shaft coupling portion 202 coupled to a first distal end 206 of the shaft 118. A second distal end 316 (FIG. 3A) is coupled to a shaft motion coupling 208 of a shaft motion assembly 210.

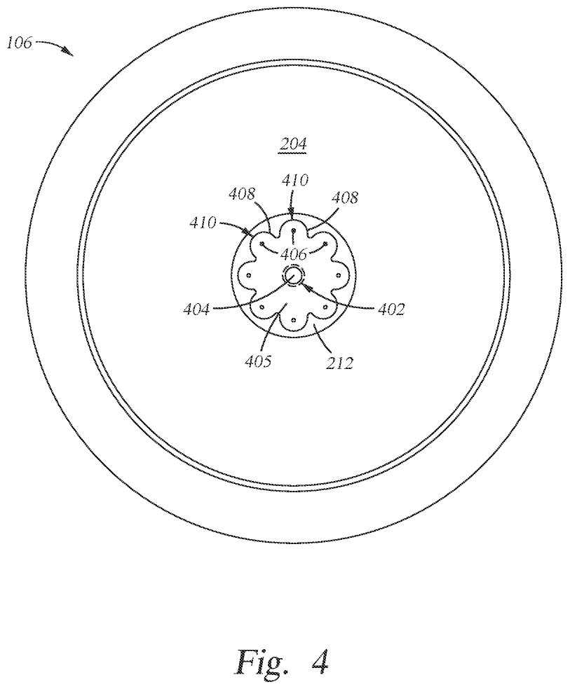

The susceptor coupling portion 212 and the shaft coupling portion 202 are fitted together, such that the shaft coupling portion 202 is inserted into a cogged indent 402 (FIG. 4) of the susceptor coupling portion 212. The cogged indent 402 and the shaft coupling portion 202 are fitted together, such that the cogged indent 402 has a shape similar (e.g., corresponding) to the shape of the shaft coupling portion 202. In some embodiments, the cogged indent 402 has an inverse shape to the shaft coupling portion 202, such that an indent is formed with the same shape and dimensions as the shaft coupling portion 202. Therefore, the susceptor coupling portion 212 may be considered a female portion of the coupling while the shaft coupling portion 202 is considered a male portion of the coupling.

The coupling surface 204 is a bottom surface of the susceptor 106, such that the coupling surface 204 is disposed opposite a substrate receiving surface or a substrate support surface. The substrate support surface is a top surface of the susceptor 106 on which the substrate 102 is disposed. The susceptor coupling portion 212 is a portion of the coupling surface 204, such that the susceptor coupling portion 212 extends from a center of the coupling surface 204 away from the top surface and the coupling surface 204 of the susceptor 106.

The second distal end 316 of the shaft 118 is coupled to the shaft motion coupling 208. The second distal end 316 is disposed on the opposite end of the shaft 118 from the first distal end 206. The shaft motion coupling 208 is an upper portion of the shaft motion assembly 210. The shaft motion assembly 210 is a portion of a rotation assembly and may be a part of the motion assembly 121, such as the rotary actuator 122 of FIG. 1. The shaft motion assembly 210 includes one or more motors or actuators and is configured to enable rotation of the shaft motion coupling 208 and subsequently the shaft 118 and the susceptor 106.

FIG. 3A is a cross-sectional schematic view of the shaft 118. The shaft 118 includes a shaft body 318 with a first distal end 206 and a second distal end 316. The first distal end 206 is coupled to the shaft coupling portion 202. The second distal end 316 is configured to be inserted into the shaft motion coupling 208. The shaft coupling portion 202 includes a body with a coupling contact surface 312, a shaft insert surface 314 disposed opposite the coupling contact surface 312, and an outer surface 310 disposed between the coupling contact surface 312 and the shaft insert surface 314. The coupling contact surface 312 further includes a plurality of features 302 disposed therein to be coupled to a plurality of features 406 (FIG. 4) which are disposed in the susceptor coupling portion 212.

The shaft body 318 is a cylindrical body. The shaft body 318 is formed of an optically transparent material, such as quartz. The use of an optically transparent material as the shaft body 318 reduces the shadowing effect of the shaft body 318 on the susceptor 106. The second distal end 316 of the shaft body 318 has a smaller diameter than the first distal end 206, such that an outer surface 320 of the shaft body 318 has a larger diameter at the first distal end 206 of the shaft body 318 than the diameter at the second distal end 316 of the shaft body 318.

A top surface 306 of the shaft 118 is configured to be disposed within a shaft receiving opening 308 of the shaft coupling portion 202. The shaft receiving opening 308 is configured to have the first distal end 320 of the shaft disposed therein, such that the top surface 306 of the shaft 118 supports the weight of the shaft coupling portion 202 and any susceptor 106 or substrate 102 disposed thereon. The shaft receiving opening 308 is disposed through the shaft insert surface 314 and the shaft 118 is inserted into the shaft receiving opening 308. The shaft receiving opening 308 and the top surface 306 of the shaft 118 may be fused, bonded, welded, or brazed together. In some embodiments, the shaft receiving opening 308 and the top surface 306 are removed, such that the shaft 118 is formed of a single monolithic piece of material.

The coupling contact surface 312 is disposed on an opposite side of the shaft coupling portion 202 from the shaft 118. The coupling contact surface 312 is configured to be inserted into the cogged indent 402, thus functioning as a mating feature. The susceptor 106 is configured to rest on the coupling contact surface 312 to facilitate mating and/or engagement therebetween. The coupling contact surface 312 includes a plurality of features 302 and a central alignment opening 304. The plurality of features 302 are a plurality of indents extending into the coupling contact surface 312. The plurality of features 302 are configured to receive the plurality of features 406 (FIG. 4) which extend from the corresponding cogged indent 402. The plurality of features 406 of the cogged indent 402 are a first plurality of features while the plurality of features 302 of the coupling contact surface 312 are a second plurality of features. The first plurality of features extend into (e.g., engage and/or interface with) the first plurality of features.

The plurality of features 302 assist in aligning the coupling contact surface 312 relative to the cogged indent 402 and reduce variation and movement of the cogged indent 402 relative to the coupling contact surface 312. The central alignment opening 304 is configured to receive a protrusion from the center of the cogged indent 402. The central alignment opening 304 is configured to align the shaft coupling portion 202 centrally with the cogged indent 402.

FIG. 3B is a schematic plan view of a shaft coupling portion 202. As illustrated, the shaft coupling portion 202 includes a plurality of projections 322 extending outward from a central portion of the shaft coupling portion 202 and the coupling contact surface 312. The plurality of projections 322 are teeth or protrusions extending outward and configured to interlock with a corresponding portion of the cogged indent 402. Each of the plurality of projections 322 include a curved outer surface 324. The curved outer surfaces 324 form side surfaces of each of the projections 322, such that the curved outer surfaces 324 are configured to be compressed when the shaft 118 is rotated to cause rotation of the susceptor 106. In some embodiments, the curved outer surfaces 324 of each of the projections 322 form a semicircle. An outermost surface of each of the plurality of projections 322 is the outer surface 310 of the shaft coupling portion 202.

One feature 302 of the plurality of features 302 is disposed in each of the projections 322, such that each of the projections 322 include a feature 302 disposed along a centerline thereof. In some embodiments, there are less features 302, such that there is less than one feature 302 for every projection 322, such that the ratio of features 302 to projections 322 is about 1:3 to about 1:1, such as about 1:2.5 to about 1:1.5, such as about 1:2.

By utilizing a plurality of projections 322, the stress imparted on any one portion of the shaft coupling portion 202 during rotation is decreased. However, the number of projections 322 may be limited as an increase in the number of projections 322 causes the structural integrity of each of the projections 322 to decrease and makes manufacturing of the shaft coupling portion 202 more difficult. In some embodiments, there are 3 or more projections 322, such as 5 to 12 projections 322, such as 6 to 10 projections 322, such 7 to 9 projections, such as 8 projections.

FIG. 4 is a schematic bottom view of a susceptor 106. The cogged indent 402 is disposed within the susceptor coupling portion 212. The cogged indent 402 includes a central opening 405 and a plurality of wings 410 extending from the central opening 405 outward across the susceptor coupling portion 212. The plurality of wings 410 are extensions of the central opening 405 and substantially match the shape of the shaft coupling portion 202 and the plurality of projections 322 with the shape of the cogged indent 402. The cogged indent further includes a central alignment projection 404. The central alignment projection 404 is configured to be fitted into the central alignment opening 304 of the shaft coupling portion 202. Each of the plurality of wings 410 of the cogged indent 402 include a sidewall 408. The sidewall 408 of each wing 410 of the cogged indent 402 has a curved portion, such that at least a portion of each wing 410 has a curved sidewall 408.

Each of the sidewalls 408 are configured to be compressed when the shaft 118 is rotated to cause rotation of the susceptor 106. In some embodiments, the sidewalls 408 of each of the wings 410 form a semicircle. Each of the sidewalls 408 are curved to distribute a compressive force which is imparted by the projections 322 of the shaft coupling portion 202 over a larger surface and reduce deformation and possible damage to the susceptor 106.

One feature 406 of the plurality of feature 406 is disposed in each of the wings 410, such that each of the wings 410 include a feature 406 disposed along a centerline thereof. In some embodiments, there are less feature 406, such that there is less than one feature 406 for every wing 410, such that the ratio of features 306 to wings 410 is about 1:3 to about 1:1, such as about 1:2.5 to about 1:1.5, such as about 1:2. Each of the features 406 of the cogged indent 402 are pins which extend from a bottom surface of the cogged indent 402 and into one of the features 302 of the shaft coupling portion 202.

In some alternate embodiments, the features 302 are pins while the features 406 are indents configured to receive the pins which form the features 302 of the shaft coupling portion 202.

By utilizing a plurality of wings 410, the stress imparted on any one portion of the cogged indent 402 during rotation is decreased. However, the number of wings 410 may be limited as an increase in the number of wings 410 causes the structural integrity of each of the wings 410 to decrease and makes manufacturing of the cogged indent 402 more difficult. In some embodiments, there are 3 or more wings 410, such as 5 to 12 wings 410, such as 6 to 10 wings 410, such 7 to 9 wings 410, such as 8 wings 410.

The susceptor 106 is formed of a highly-thermally conductive material to enable uniform thermal distribution across the susceptor 106. The susceptor 106 may therefore be a graphite or a silicon carbide material. In some embodiments, the susceptor 106 is a quartz material to make the susceptor 106 optically transparent to light emitted by lamps within the deposition chamber 100.

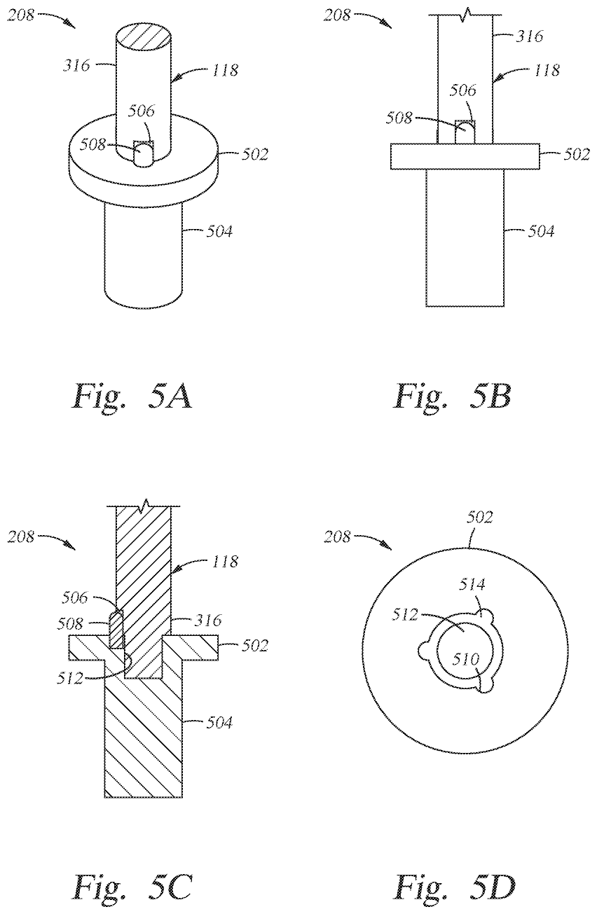

FIGS. 5A-5D are schematic views of portions of the shaft motion coupling 208. FIG. 5A is a schematic isometric view of the shaft motion coupling 208 with the shaft 118 disposed therein. The shaft motion coupling 208 includes a flange 502 into which the second distal end 316 of the shaft 118 is inserted. The flange 502 has a lower shaft 504 which may be disposed within the shaft motion assembly 502. A plurality of pin rollers 508 are disposed between grooves 506 within the second distal end 316 of the shaft 118 and the flange 502. The plurality of pin rollers 508 assist in holding the shaft 118 in place relative to the flange 502.

FIG. 5B is a schematic side view of the shaft motion coupling 208 with the shaft 118 disposed therein. As shown in FIG. 5B, each of the grooves 506 is disposed within the second distal end 316 of the shaft 118, such that the grooves 506 extend inward into the shaft 118.

FIG. 5C is a schematic cross-sectional view of the shaft motion coupling 208 with the shaft 118 disposed therein. The pin rollers 508 have cylindrical sidewalls and extend into a radial appendage 514 of a central opening 512 of the flange 502. The central opening 512 of the flange 502 is an opening configured to receive the second distal end 316 of the shaft 118 within the flange 502. The inside surface of the central opening 512 may be aligned with an inside of one of the grooves 506.

FIG. 5D is a schematic plan view of the shaft motion coupling 208. As shown in FIG. 5D, each of the radial appendages 514 are extensions of the central opening 512 and extend outward. The central opening 512 includes a sidewall 510. The sidewall 510 is circular with the radial appendages 514 forming protrusions from the circle forming the sidewall 510. A pin roller 508 is disposed within each of the radial appendages 514, such that each of the pin rollers 508 are disposed between the sidewall 510 and the shaft 118. The shape of the radial appendages 514 and the grooves 506 are configured to hold the pin rollers 508 in place and the pin rollers 508 are configured to couple the motion of the flange 502 to the shaft 118.

In some embodiments, there are two or more pin rollers 508 and two or more radial appendages 514, such as three or more pin rollers 508 and three or more radial appendages 514. The use of multiple pin rollers 508 and radial appendages 514 assists in distributing the load on any one surface of the shaft 118 and prevents fracturing or chipping of the shaft 118.

Each of the pin rollers 508 are formed of a thermoplastic, a metal, a graphite, or a silicon carbide material. The pin rollers 508 are configured to endure the stress of imparting rotation onto the shaft 118 without fracturing or large amounts of deformation. The flange 502 is formed of a metal or a metal alloy, such as one or more of nickel, chromium, molybdenum, and niobium. The flange 502 is configured to have reduced deformation while imparting a high amount of force to the pin rollers 508 and the shaft 118.

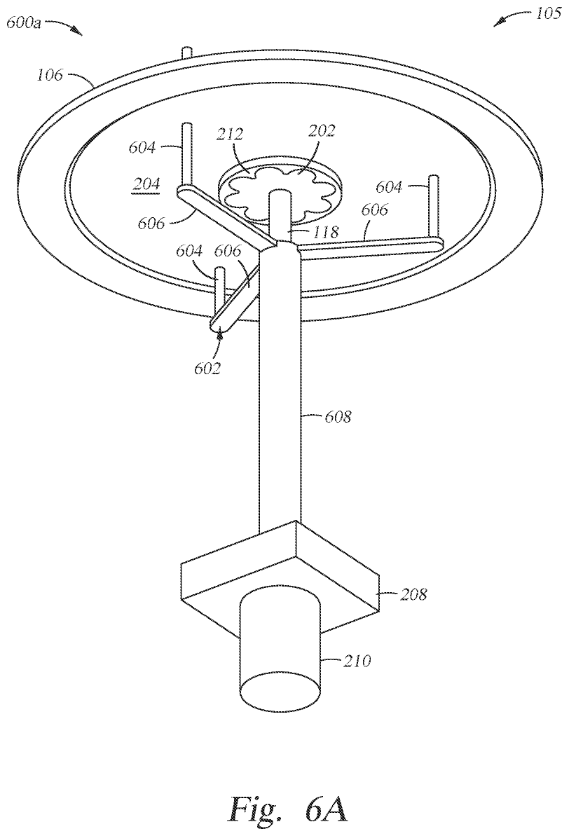

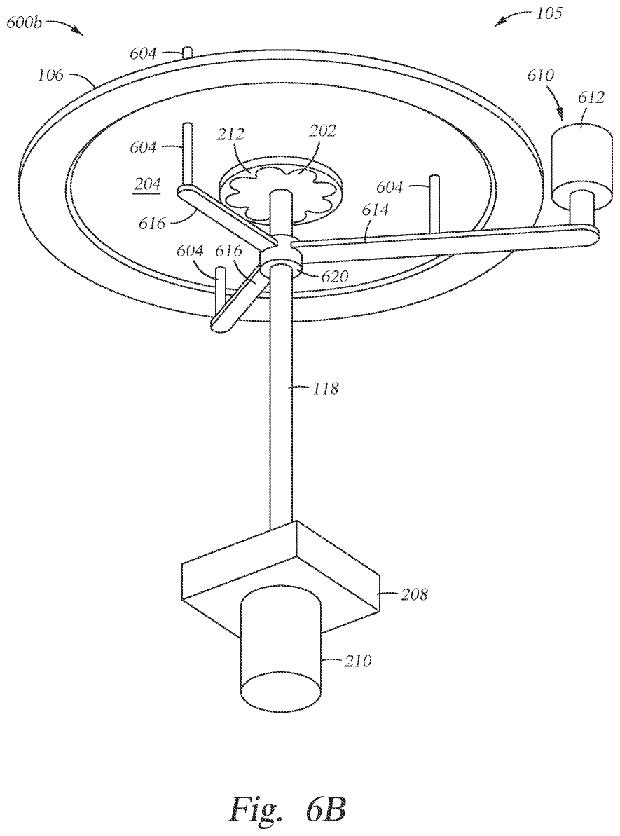

FIGS. 6A and 6B are schematic isometric views of substrate support assemblies 600a, 600b. The substrate support assemblies 600a, 600b of FIGS. 6A and 6B further illustrate various lift pin apparatus which may be used to raise and lower a substrate from the susceptor 106, such that a plurality lift pins 604 are sent through the susceptor 106 to raise and lower a substrate. The lift pins 604 within each of the substrate support assemblies 600a, 600b are formed of a quartz material.

FIG. 6A illustrates a substrate support assembly 600a which includes a lift pin assembly. The lift pin assembly forms a sleeve 608 disposed around the shaft 118. The sleeve 608 extends from the shaft motion coupling 608 to an upper portion of the shaft 118. The sleeve 608 is a hollow cylinder which surrounds the shaft 118. A plurality of lift pin support arms 606 extend outward from the sleeve 608. A lift pin 604 is disposed on top of each of the lift pin support arms 606 at a distal end 602 opposite the sleeve 608. The lift pin support arms 606 may be one of a quartz material, a silicon carbide material, or a graphite material.

In embodiments described herein, the lift pin support arms 606 are a disposed at a normal angle to the lift pins 604 themselves. There is a single lift pin 604 extending from each of the lift pin support arms 606. The single lift pin 604 extends upwards from the lift pin support arm 606 away from the sleeve 608. There are three or more lift pin support arms 606 and lift pins 604, such as four or more lift pin support arms 606 and lift pins 604.

FIG. 6B illustrates a substrate support assembly 600b which utilizes a linear motion device 610 disposed on a side of the substrate support assembly 105. At least a portion of the linear motion device 610 of the substrate support assembly 600b may be disposed outside of the processing volume 136. The linear motion device 610 includes a linear actuator 612 and a Y-shaped lift pin support member 614 extending into the processing volume 136 towards the shaft 118. The lift pin support member 614 includes a central neck 620 at a distal end of the lift pin support member 614 distal from the linear actuator 612. The central neck 620 is a ring disposed around the shaft 118. Two arms 616 extend from the central neck 620 and away from the lift pin support member 614. The two arms 616 are similar in length and include a lift pin 604 disposed at a distal end thereon from the central neck 620 and extending upwards through the susceptor 106. A third lift pin 604 is disposed on the lift pin support member 614 and extends upwards from the lift pin support member 614. The third lift pin 604 is disposed between the connection to the linear actuator 612 and the central neck 620.

The substrate support assemblies 600a, 600b described herein are at least partially enabled by the use of a single shaft 118 and the cogged interface between the substrate 106 and the shaft 118. The substrate support assemblies 600a, 600b are configured to have reduced shadowing on the susceptor.

Embodiments of the substrate support assembly 105 described herein are configured to have reduced shadowing and reduced wobble compared to other substrate support assemblies 105. The use of reciprocal mating features, such as cogged features, to couple the shaft 118 and the susceptor 106 enable reduced shadowing and reduced wobble. As the susceptor 106 and the shaft 118 are heated, the thermal expansion of the cogged feature may further reduce the movement of the susceptor and the substrate disposed thereon.

While the foregoing is directed to embodiments of the present disclosure, other and further embodiments of the disclosure may be devised without departing from the basic scope thereof, and the scope thereof is determined by the claims that follow.

What is claimed is:

1. A substrate support assembly, configured for use in semiconductor processing, comprising:
a susceptor comprising:
a substrate support surface;
a coupling surface; and
a cogged indent within the coupling surface; and
a shaft comprising:
a first distal end; and
a second distal end opposite the first distal end; and
a shaft coupling portion coupled to the first distal end of the shaft and disposed within the cogged indent.

2. The substrate support assembly of claim 1, wherein the cogged indent includes a central opening and a plurality of wings extending from the central opening outward across the coupling surface.

3. The substrate support assembly of claim 2, wherein each of the plurality of wings are extensions of the central opening and three or more wings extend radially outward from the central opening.

4. The substrate support assembly of claim 3, wherein the central opening has a circular cross-section.

5. The substrate support assembly of claim 1, wherein the cogged indent further include a plurality of first features.

6. The substrate support assembly of claim 5, wherein the shaft coupling portion further includes a plurality of second features on a coupling surface of the shaft coupling portion.

7. The substrate support assembly of claim 6, wherein the first features are a plurality of pins extending from the cogged indent and the plurality of second features are a plurality of indents extending into the coupling surface and the plurality of pins extend into the plurality of indents.

8. The substrate support assembly of claim 1, further comprising a shaft motion coupling coupled to the second distal end of the shaft.

9. The substrate support assembly of claim 8, wherein the shaft motion coupling includes a central opening, a plurality of radial appendages extending outward from the central opening, and the second distal end of the shaft includes a plurality of grooves disposed therein.

10. The substrate support assembly of claim 9, wherein the plurality of radial appendages are extensions of the central opening and a pin is disposed between each of the radial appendages and each of the grooves.

11. A susceptor, configured for use in semiconductor processing, comprising:
a substrate support surface;
a coupling surface opposite the substrate support surface; and
a cogged indent disposed within the coupling surface and further comprising:
a central opening; and
a plurality of wings extending from the central opening outward across the coupling surface.

12. The susceptor of claim 11, wherein at least a portion of a wall of each of the plurality of wings is curved.

13. The susceptor of claim 11, wherein three or more wings extend radially outward from the central opening.

14. The susceptor of claim 11, wherein the susceptor is formed of a graphite material.

15. The susceptor of claim 11, wherein the substrate support surface is circular.

16. A shaft, configured for use in semiconductor processing, comprising:
a first distal end;
a second distal end opposite the first distal end; and
a shaft coupling portion coupled to the first distal end of the shaft and comprising:
a coupling contact surface; and
a plurality of projections extending outward from a central portion of the coupling contact surface, such that the coupling contact surface is cogged.

17. The shaft of claim 16, further comprising a plurality of features on the coupling contact surface of the shaft coupling portion.

18. The shaft of claim 17, wherein the plurality of features are a plurality of indents extending into the coupling contact surface.

19. The shaft of claim 16, wherein there are three or more projections.

20. The shaft of claim 16, wherein the second distal end of the shaft further comprises a plurality of grooves.
